(19) United States
(12) Patent Application Publication
(10) Pub. No.: US 2007/0164440 A1
(43) Pub. Date: Jul. 19, 2007

(54) Semiconductor device, dicing saw and method for manufacturing the semiconductor device

(76) Inventor: Takayuki Matsuda, Kyoto (JP)

Correspondence Address: MCDERMOTT WILL & EMERY LLP, 600 13TH STREET, N.W., WASHINGTON, DC, 20005-3096, US

(21) Appl. No.: 11/545,426

(22) Filed: Oct. 11, 2006

(30) Foreign Application Priority Data
Jan. 13, 2006 (JP) 2006-005845

(51) Int. Cl. H01L 21/44

(52) U.S. Cl. 257/762; 438/687; 438/637; 438/648; 257/774

(57) ABSTRACT

A first interlayer insulating film and a second interlayer insulating film are formed on a semiconductor substrate and first Cu interconnections are formed in the first interlayer insulating film and second Cu interconnections are formed in the second interlayer insulating film. Pad electrodes are formed on the second Cu interconnections with a barrier metal interposed therebetween. The pad electrodes are made of AlCu containing Mg.

### BACKGROUND OF THE INVENTION

1. Field of the Invention

The present invention relates to a semiconductor device, a dicing saw and a method for manufacturing the semiconductor device.

2. Description of Related Art

According to reduction in chip size due to miniaturization of semiconductor devices in recent years and increase in diameter of a wafer on which the semiconductor devices are formed, time required for dicing a single wafer to separate the semiconductor devices has been getting longer.

Hereinafter, explanation of a conventional technique of dicing the wafer is provided. FIG. 8A illustrates the conventional technique of dicing the wafer. According to the conventional dicing technique, acidic cooling water containing CO₂ dissolved therein is sprayed from pipes 124a and 124b and basic cooling water containing NH₃ dissolved therein is sprayed from a pipe 124c at high pressure onto a rotation saw 123 contacting a wafer 121. In this technique, the acidic cooling water is neutralized by the basic cooling water, thereby preventing corrosion and static buildup of terminal electrodes exposed on the substrate surface, as well as decrease in adhesion to external leads.

FIG. 8B is a sectional view illustrating a conventional interconnection structure (see, for example, Japanese Unexamined Patent Publication No. H03-235350).

As shown in FIG. 8B, interlayer insulating films 111 and 113 are formed on a semiconductor substrate 110. Cu interconnections 112 and 114 are formed in the interlayer insulating films 111 and 113, respectively, and pad electrodes 118 are formed on the Cu interconnections 114. In general, the pad electrodes 118 are made of AlCu.

If the pad electrodes are made of pure Al, electrons are likely to displace Al to cause EM (electromigration). However, the pad electrodes made of AlCu reduce the possibility of EM.

Further, the pad electrodes made of AlCu are advantageous in that gold wires are favorably adhered thereto because Al and Au are likely to be alloyed and the AlCu electrodes and other Al interconnections are formed using the same production equipment.

### SUMMARY OF THE INVENTION

The conventional dicing technique, however, has the following problem.

As the dicing time gets longer due to the increase in wafer diameter and the miniaturization of the semiconductor devices, the wafer has to be in contact with the cooling water or wash water for a longer time during the dicing. Therefore, Al contained in the pad electrodes 118 is corroded to cause failure in the later step of bonding wires, thereby decreasing the reliability of the semiconductor devices.

The present invention has been achieved to solve the above problem. An object of the present invention is to provide a semiconductor device, a dicing saw and a method for manufacturing the semiconductor device while the corrosion of the pad electrodes is prevented.

According to a first aspect of the present invention, a semiconductor device includes: a semiconductor substrate; an insulating film formed on the semiconductor substrate; an interconnection formed on the insulating film and contains a first metal; and an electrode electrically connected to the interconnection and contains a second metal and an element having a higher ionization tendency than the second metal, wherein the content of the element in the electrode is lower than the content of the second metal in the electrode.

In the semiconductor device according to the first aspect of the present invention, the electrode contains the element having a higher ionization tendency than the second metal. The element is more likely to be ionized than the second metal when cutting the semiconductor device from the wafer by dicing. As a result, the second metal is inhibited from dissolving into liquid during the dicing, thereby preventing the corrosion of the electrode. Therefore, in the later step of bonding a wire to the electrode, adhesion between the wire and the electrode is improved, thereby preventing failure in bonding the wire and improving the reliability of the semiconductor device.

In the semiconductor device according to the first aspect of the present invention, the ionization tendency of the first metal may be lower than that of the second metal.

In the semiconductor device according to the first aspect of the present invention, the first metal may be Cu, the second metal may be Al and the element may be Mg, Li, K or Ca.

A dicing saw according to the first aspect of the present invention for dicing a semiconductor substrate contains an element having a higher ionization tendency than Al.

Since the dicing saw according to the first aspect of the present invention contains the element having a higher ionization tendency than Al, the element is more likely to be ionized than Al when dicing the semiconductor substrate. As a result, even if the interconnection and the electrode on the semiconductor substrate are made of metals having different ionization tendencies, these metals are less likely to cause corrosion therebetween, thereby inhibiting the metals from dissolving into liquid. Therefore, the corrosion of the electrode is prevented.

As to the dicing saw according to the first aspect of the present invention, the element may be Mg, Li, K or Ca.

A method for manufacturing the semiconductor device according to the first aspect of the present invention includes the steps of: (a) forming an insulating film on a semiconductor substrate; (b) forming an interconnection containing a first metal on the insulating film; and (c) forming an electrode electrically connected to the interconnection and contains a second metal and an element having a higher ionization tendency than the second metal, wherein the content of the element in the electrode is lower than the content of the second metal in the electrode.

As to the method according to the first aspect of the present invention, the electrode contains the element having a higher ionization tendency than the second metal. Therefore, the element is more likely to be ionized than the second metal when dicing the wafer. As a result, the second metal is inhibited from dissolving into liquid during the dicing, thereby preventing the corrosion of the electrode. Therefore, in the later step of bonding a wire to the electrode, adhesion between the wire and the electrode is improved, thereby preventing failure in bonding the wire and improving the reliability of the semiconductor device.

In the method according to the first aspect of the present invention, the ionization tendency of the first metal is higher than that of the second metal.

In the method according to the first aspect of the present invention, the first metal may be Cu, the second metal may be Al and the element may be Mg, Li, K or Ca.

A method for manufacturing a semiconductor device according to a second aspect of the present invention includes the step of dicing a semiconductor substrate, wherein the semiconductor device includes an interconnection containing a first metal and an electrode electrically connected to the interconnection and contains a second metal having a higher ionization tendency than the first metal and the dicing is carried out using a dicing saw containing an element having a higher ionization tendency than that of the second metal.

As to the method according to the second aspect of the present invention, the element contained in the dicing saw is more likely to be ionized than the second metal contained in the electrode when dicing the semiconductor substrate. As a result, the second metal is inhibited from dissolving into liquid, thereby preventing the corrosion of the electrode. Therefore, in the later step of bonding a wire to the electrode, adhesion between the wire and the electrode is improved, thereby preventing failure in bonding the wire and improving the reliability of the semiconductor device.

In the method according to the second aspect of the present invention, the element may be Mg, Li, K or Ca.

A method for manufacturing a semiconductor device according to a third aspect of the present invention includes the step of dicing a semiconductor substrate, wherein the semiconductor device includes an interconnection containing a first metal and an electrode electrically connected to the interconnection and contains a second metal having a higher ionization tendency than the first metal and the dicing is carried out while an ionization inhibitor for inhibiting the ionization of the second metal is supplied.

As to the method according to the third aspect of the present invention, the second metal is less likely to be ionized when dicing the semiconductor substrate, thereby preventing the corrosion of the electrode. Therefore, in the later step of bonding a wire to the electrode, adhesion between the wire and the electrode is improved, thereby preventing the failure in bonding the wire and improving the reliability of the semiconductor device.

In the method according to the third aspect of the present invention, the ionization inhibitor is an element having a higher ionization tendency than the second metal and the dicing is carried out while liquid containing the element is supplied.

In this case, the element may be Mg, Li, K or Ca.

In the method according to the third aspect of the present invention, the ionization inhibitor may be a basic buffer solution and the dicing is carried out while the basic buffer solution may be supplied.

In the method according to the third aspect of the present invention, the ionization inhibitor is hydrogen and the dicing is carried out while liquid is supplied in an atmosphere where hydrogen partial pressure is higher than that in atmospheric air.

### BRIEF DESCRIPTION OF THE DRAWINGS

FIG. 1 is a view for illustrating the principle of embodiments of the present invention.

FIG. 2 is a sectional view illustrating the structure of a semiconductor device according to a first embodiment of the present invention.

FIGS. 3A to 3D are sectional views illustrating the steps of a method for manufacturing the semiconductor device according to the first aspect of the present invention.

FIG. 4 is a schematic view illustrating a dicing step according to a second embodiment of the present invention.

FIG. 5 is a schematic view illustrating a dicing step according to a third embodiment of the present invention.

FIG. 6 is a schematic view illustrating a dicing step according to a fourth embodiment of the present invention.

FIG. 7 is a schematic view illustrating a dicing step according to a fifth embodiment of the present invention.

FIG. 8A is a view illustrating a conventional dicing technique and FIG. 8B is a sectional view illustrating a conventional interconnection structure.

### DETAILED DESCRIPTION OF THE INVENTION

### (Principle of the Invention)

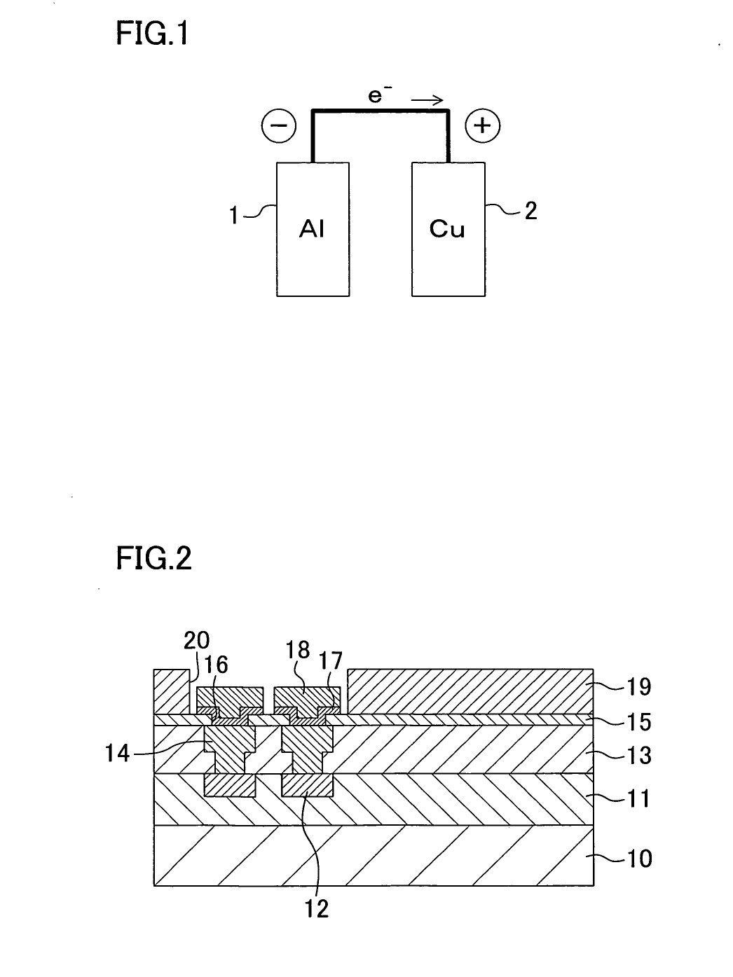

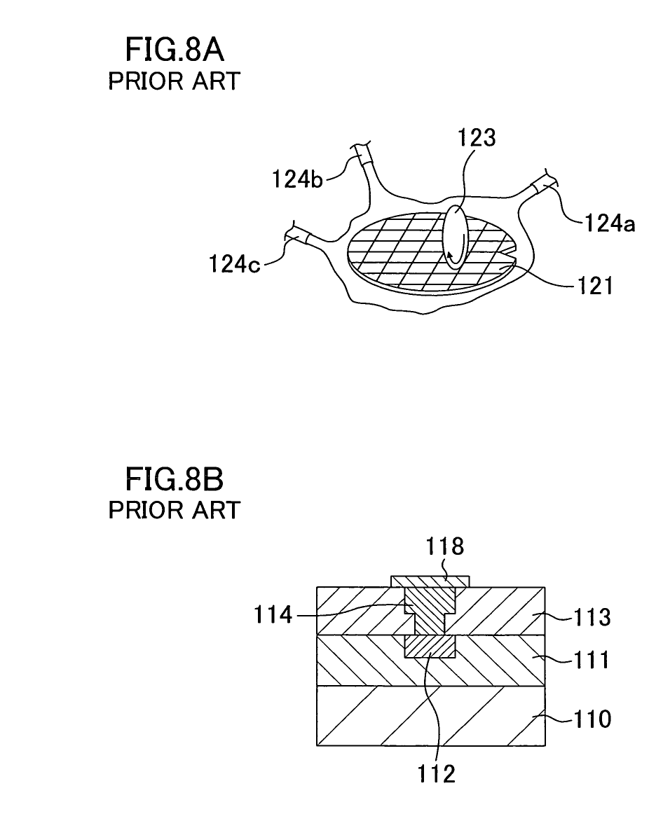

As shown in FIG. 8B, the pad electrodes 118 contain Al. The ionization tendency of Al is significantly higher than that of Cu contained in the Cu interconnections 114. Therefore, Al is more likely to release electrons than Cu at the interface between the pad electrodes 118 and the Cu interconnections 114. As a result, Al in the pad electrodes 118 and Cu in the Cu interconnections 114 serve as a negative electrode 1 and a positive electrode 2, respectively, as shown in FIG. 1, thereby causing battery effect at the interface therebetween and promoting the ionization of Al.

The present invention takes the ionization tendency into account to inhibit the Al ionization.

### First Embodiment

FIG. 2 is a sectional view illustrating the structure of a semiconductor device according to a first embodiment of the present invention. As shown in FIG. 2, the semiconductor device of the present embodiment includes a first interlayer insulating film 11 formed on a semiconductor substrate 10 and a second interlayer insulating film 13 formed on the first interlayer insulating film 11. Further, though not shown, components such as MISFETs are also formed on the semiconductor substrate 10.

First Cu interconnections 12 are formed in a top portion of the first interlayer insulating film 11. Though it is not shown in the sectional view of FIG. 2, the first Cu interconnections 12 are connected to the components formed on the semiconductor substrate 10, e.g., the MISFETs (not shown). Further, second Cu interconnections 14 are formed in the second interlayer insulating film 13 to be in contact with the first Cu interconnections 12.

A first surface protection film 15 made of a silicon nitride (SiN) film is formed on the second interlayer insulating film 13. The first surface protection film 15 is provided with openings 16 for exposing the second Cu interconnections 14. In the openings 16, a pad electrodes 18 are formed with a barrier metal 17 made of TiN interposed therebetween. The pad electrodes 18 are made of an AlCu film containing Mg. The content of Mg in the pad electrodes 18 is not particularly limited, but it has to be lower than the Al content. The Mg content is preferably in the range of 0.5% or higher and 10% or lower. The Cu content in the AlCu film is about 0.5%, for example, which is usually lower than the Al content. In comparison between Al and Cu, the ionization tendency and the content of Al are higher than those of Cu.

The AlCu film as the material for the pad electrodes 18 may be replaced with an Al film containing Mg or an AlSiCu film containing Mg. If the AlSiCu film is used, the contents of Cu and Si are set smaller than the Al content.

A second surface protection film 19 made of SiN is formed on the first surface protection film 15. The second surface protection film 19 is provided with an opening 20 for exposing the pad electrodes 18.

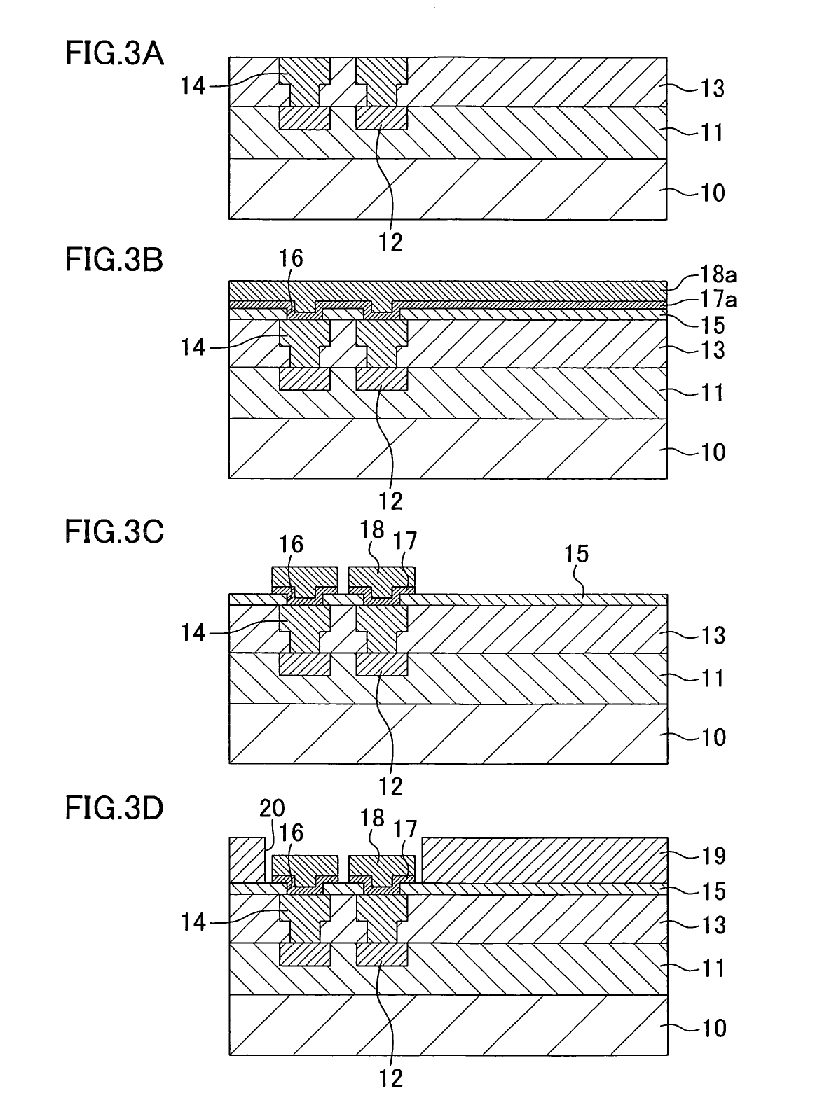

FIGS. 3A to 3D are sectional views for illustrating the steps for manufacturing the semiconductor device according to the first embodiment of the present invention. First, in order to obtain the structure shown in FIG. 3A, a first interlayer insulating film 11 is formed on a semiconductor substrate 10 and first Cu interconnections 12 are formed in a top portion of the first interlayer insulating film 11. Then, a second interlayer insulating film 13 is formed on the first interlayer insulating film 11 and second Cu interconnections 14 are formed to penetrate the second interlayer insulating film 13 to reach the first Cu interconnections 12.

Then, in the step shown in FIG. 3B, a first surface protection film 15 made of SiN is formed over the second interlayer insulating film 13 and the second Cu interconnections 14. Openings 16 are then formed in the first surface protection film 15 to expose the second Cu interconnections 14 and a TiN film 17a is formed to bury the openings 16. Further, an Mg-containing AlCu film 18a is formed on the TiN film 17a.

In the step shown in FIG. 3C, a resist (not shown) is formed on the Mg-containing AlCu film 18a and The TiN film 17a and the Mg-containing AlCu film 18a are patterned using the resist as a mask. Thus, a barrier metal 17 and pad electrodes 18 are formed. Then, the resist is removed.

In the step shown in FIG. 3D, a second surface protection film 19 made of SiN is formed to cover the first surface protection film 15 and the pad electrodes 18. Then, the second surface protection film 19 is patterned to form an opening 20 for exposing the pad electrodes 18.

In the present embodiment, the pad electrodes 18 contain Mg showing a higher ionization tendency than Al. Therefore, when dicing the wafer, Mg is more likely to be ionized than Al. As a result, corrosion between metals of different kinds, i.e., Cu and Al, is less prone to occur and Al ions are inhibited from dissolving into cooling water or wash water. Thus, the corrosion of the pad electrodes 18 is prevented. In the later step of bonding Au wires to the pad electrodes 18, the Au wires are well adhered to the pad electrodes 18, thereby forming an alloy of Al and Au with ease. Thus, the wire bonding is carried out without failure and the reliability of the semiconductor device improves.

### Second Embodiment

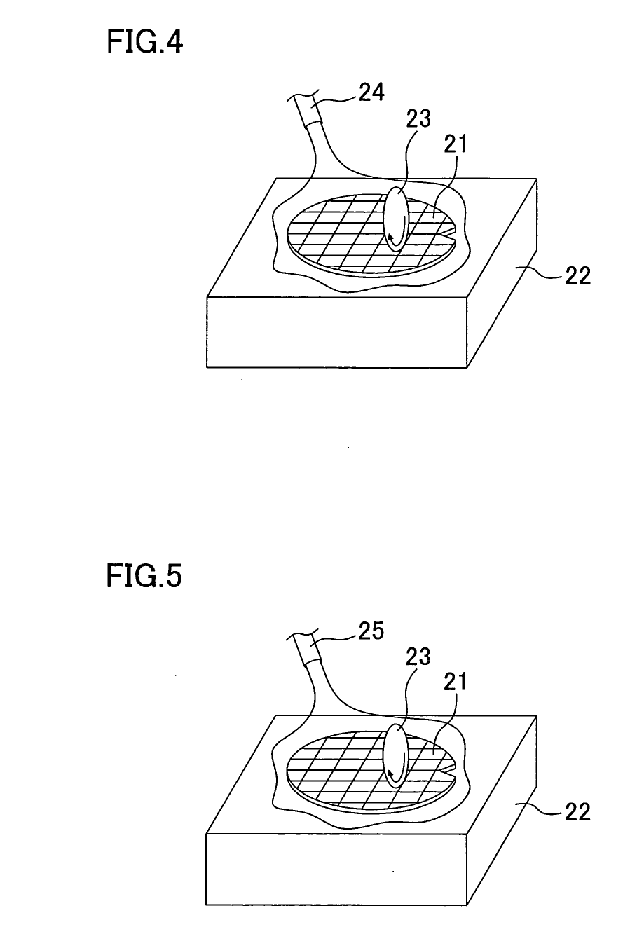

FIG. 4 schematically shows a dicing step according to a second embodiment of the present invention. Referring to FIG. 4, a wafer 21 is fixed onto a dicing stage 22 and subjected to dicing with a dicing saw (rotary saw) 23. During the dicing, a pipe 24 supplies cooling water containing Mg (Mg ions). The Mg concentration in the cooling water is not particularly limited. If the Mg concentration is about 0.5 mol %, the dicing is carried out easily because Mg is dissolved in the cooling water by merely immersing Mg in the cooling water.

The pipe 24 may supply wash water instead of the cooling water.

The wafer 21 may include Cu interconnections and AlCu pad electrodes as in the structure shown in FIG. 8B. The wafer may include other interconnections and electrodes as long as the interconnections contain Cu and the pad electrodes contain Al.

In the present embodiment, the cooling water or wash water used in the dicing step contains Mg showing a higher ionization tendency than Al. Therefore, when dicing the wafer, Al is less likely to be ionized and the metals of different kinds, i.e., Cu and Al, are less prone to cause corrosion therebetween. Thus, the corrosion of the pad electrodes 18 is prevented. in the later step of bonding Au wires to the pad electrodes 18, the Au wires are well adhered to the pad electrodes 18, thereby forming an alloy of Al and Au. Thus, the wire bonding is carried out without failure and the reliability of the semiconductor device improves.

### Third Embodiment

FIG. 5 schematically shows a dicing step according to a third embodiment of the present invention. Referring to FIG. 5, a wafer 21 is fixed onto a dicing stage 22 and subjected to dicing with a dicing saw 23. During the dicing, a pipe 25 supplies a basic buffer solution. The basic buffer solution may be a Tris methylamine solution.

The following reaction formulae (1) and (2) represent how Al contained in the pad electrodes is ionized and dissolved into liquid.

Al→Al³⁺+3e⁻ (1)

3e⁻+2H⁺→H₂↑ (2)

As shown in the reaction formula (1), the ionization of Al generates e⁻. However, as the basic buffer solution contains a large amount of e⁻, the reaction of the formula (1), i.e., the ionization of Al, does not proceed easily when the basic buffer solution is supplied during the dicing. Therefore, the pad electrodes are less likely to be corroded. As a result, in the later step of bonding Au wires to the pad electrodes 18, the Au wires are well adhered to the pad electrodes 18, thereby forming an alloy of Al and Au. Thus, the wire bonding is carried out without failure and increasing the reliability of the semiconductor device.

In the explanation above, the Tris methylamine solution is used as the basic buffer solution. However, other basic buffer solutions than the Tris methylamine solution may also be used as long as pH of the solution is kept to 8 to 13 with stability.

The wafer 21 may include interconnections made of Cu and pad electrodes made of AlCu as in the structure shown in FIG. 8B. Specifically, the wafer may include other interconnections and electrodes as long as the interconnections contain Cu and the pad electrodes contain Al.

### Fourth Embodiment

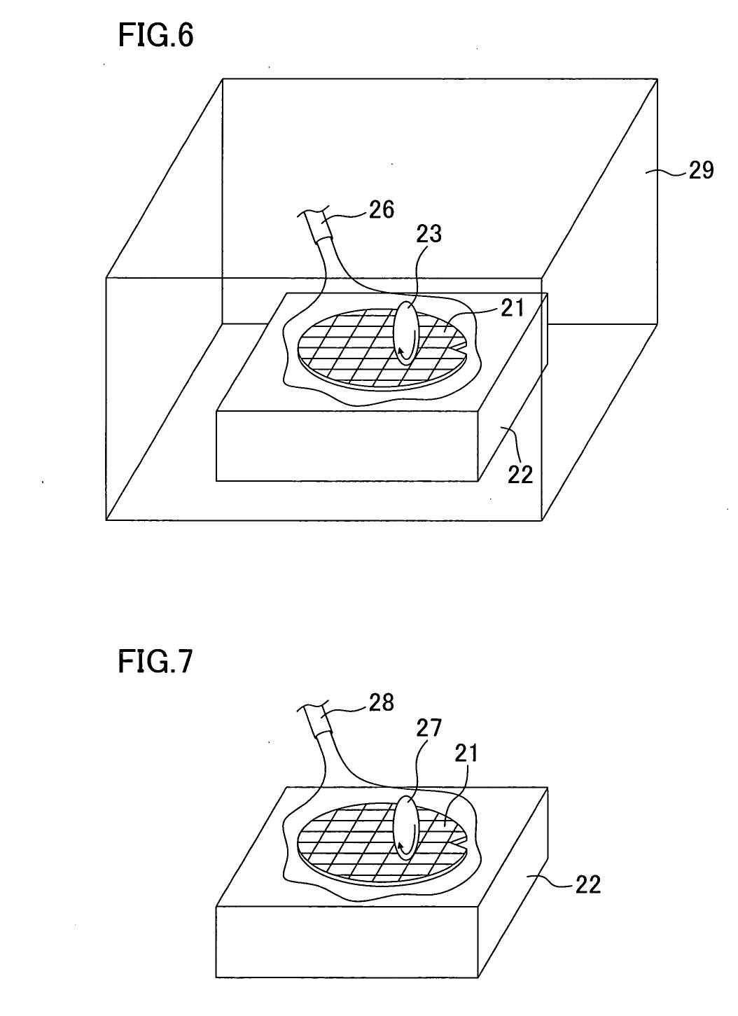

FIG. 6 schematically shows a dicing step according to a fourth embodiment of the present invention. In the present embodiment, a dicing stage 22 is placed in a casing 29 such that dicing is performed therein. During the dicing, a pipe 26 supplies cooling water or wash water.

The casing 29 contains H₂ therein. The H₂ content in the casing 29 is set higher than that in the atmospheric air. Specifically, the casing 29 contains the atmospheric air existed therein from the beginning and H₂ added thereto. It is preferred that H₂ is added up to the limit of hydrogen partial pressure. The atmospheric air does not necessarily exist in the casing 29 and H₂ may solely exist therein.

Aluminum reacts with OH⁻ existing in the cooling or wash water as shown in the formula (3) shown below. The OH⁻ is generated through decomposition of H₂O together with H₂ as shown in the formula (4).

Al³⁺→Al(OH)₃ (3)

2H₂O→2OH⁻+H₂↑ (4)

In the present embodiment, H₂ is supplied during the dicing to inhibit the decomposition of H₂O shown in the formula (4) and the generation of OH⁻. This inhibits the reaction of the formula (3) and therefore Al is less likely to be ionized. As a result, corrosion between metals of different kinds, i.e., Cu and Al, is less prone to occur, thereby preventing the corrosion of the pad electrodes 18. In the later step of bonding Au wires to the pad electrodes 18, the Au wires are well adhered to the pad electrodes 18, thereby forming an alloy of Al and Au with ease. Thus, the wire bonding is carried out without failure and the reliability of the semiconductor device improves.

The wafer 21 may include interconnections made of Cu and pad electrodes made of AlCu as in the structure shown in FIG. 8B. The wafer may include other interconnections and electrodes as long as the interconnections contain Cu and the pad electrodes contain Al.

### Fifth Embodiment

FIG. 7 schematically shows a dicing step according to a fifth embodiment of the present invention. In the present embodiment, the dicing is carried out with a dicing saw 27 made of Mg-containing metal as shown in FIG. 7. during the dicing, the wafer 21 is fixed onto a dicing stage 22 and a pipe 28 supplies cooling water or wash water. The dicing saw 27 may be made of a metallic disc having a side surface to which diamond grains are adhered. In this case, the metallic disc may contain Mg.

In the present embodiment, the dicing saw 27 contains Mg showing a higher ionization tendency than Al. Therefore, when dicing the wafer, Mg is more likely to be ionized than Al. As a result, corrosion between metals of different kinds, i.e., Cu and Al, is less prone to occur and Al ions are inhibited from dissolving into cooling water or wash water. Thus, the corrosion of the pad electrode 18 is prevented. In the later step of bonding Au wires to the pad electrodes 18, the Au wires are well adhered to the pad electrodes 18, thereby forming an alloy of Al and Au with ease. Thus, the wire bonding is carried out without failure and the reliability of the semiconductor device improves.

The wafer 21 may include interconnections made of Cu and pad electrodes made of AlCu as in the structure shown in FIG. 8B. The wafer may include other interconnections and electrodes as long as the interconnections contain Cu and the pad electrodes contain Al.

### Other Embodiments

In the above-described embodiments, Mg is used as metal having a higher ionization tendency than Al. However, other elements than Mg, for example, Li, K or Ca, may be used as the metal having a higher ionization tendency than Al.

Further, in the above-described embodiments, the interconnections made of Cu and the pad electrodes made of material containing Al are used. However, the interconnections and the pad electrodes may be made of other materials. The effect of the present invention is achieved as long as the pad electrode material shows a higher ionization tendency than the interconnection material. Therefore, the invention may be applicable even if the pad electrode material having a higher ionization tendency than the interconnection material is used.

What is claimed is:

1. A semiconductor device comprising:
a semiconductor substrate;
an insulating film formed on the semiconductor substrate;
an interconnection formed on the insulating film and contains a first metal; and
an electrode electrically connected to the interconnection and contains a second metal and an element having a higher ionization tendency than the second metal, wherein
the content of the element in the electrode is lower than the content of the second metal in the electrode.

2. The semiconductor device of claim 1, wherein
the ionization tendency of the first metal is lower than that of the second metal.

3. The semiconductor device of claim 1, wherein
the first metal is Cu, the second metal is Al and the element is Mg, Li, K or Ca.

4. A dicing saw for dicing a semiconductor substrate contains an element having a higher ionization tendency than Al.

5. The dicing saw of claim 4, wherein
the element is Mg, Li, K or Ca.

6. A method for manufacturing a semiconductor device comprising the steps of:
(a) forming an insulating film on a semiconductor substrate;
(b) forming an interconnection containing a first metal on the insulating film; and
(c) forming an electrode electrically connected to the interconnection and contains a second metal and an element having a higher ionization tendency than the second metal, wherein
the content of the element in the electrode is lower than the content of the second metal in the electrode.

7. The method of claim 6, wherein
the ionization tendency of the first metal is higher than that of the second metal.

8. The method of claim 6, wherein
the first metal is Cu, the second metal is Al and the element is Mg, Li, K or Ca.

9. A method for manufacturing a semiconductor device including the step of dicing a semiconductor substrate, wherein
the semiconductor device includes an interconnection containing a first metal and an electrode electrically connected to the interconnection and contains a second metal having a higher ionization tendency than the first metal and
the dicing is carried out using a dicing saw containing an element having a higher ionization tendency than that of the second metal.

10. The method of claim 9, wherein
the element is Mg, Li, K or Ca.

11. A method for manufacturing a semiconductor device including the step of dicing a semiconductor substrate, wherein
the semiconductor device includes an interconnection containing a first metal and an electrode electrically connected to the interconnection and contains a second metal having a higher ionization tendency than the first metal and
the dicing is carried out while an ionization inhibitor for inhibiting the ionization of the second metal is supplied.

12. The method of claim 11, wherein
the ionization inhibitor is an element having a higher ionization tendency than the second metal and
the dicing is carried out while liquid containing the element is supplied.

13. The method of claim 12, wherein
the element is Mg, Li, K or Ca.

14. The method of claim 11, wherein
the ionization inhibitor is a basic buffer solution and
the dicing is carried out while the basic buffer solution is supplied.

15. The method of claim 11, wherein
the ionization inhibitor is hydrogen and
the dicing is carried out while liquid is supplied in an atmosphere where hydrogen partial pressure is higher than that in atmospheric air.
